(19) United States
(12) Patent Application Publication
(10) Pub. No.: US 2013/0181247 A1
(43) Pub. Date: Jul. 18, 2013

(54) Semiconductor Component and Method for Producing a Semiconductor Component

(71) Applicants: Simon Jerebic, Tegernheim (DE); Erik Heinemann, Regensburg (DE); Christian Gaertner, Neutraubling (DE); Ales Markytan, Regensburg (DE)

(72) Inventors: Simon Jerebic, Tegernheim (DE); Erik Heinemann, Regensburg (DE); Christian Gaertner, Neutraubling (DE); Ales Markytan, Regensburg (DE)

(73) Assignee: OSRAM OPTO SEMICONDUCTORS GMBH, Regensburg (DE)

(21) Appl. No.: 13/811,524

(22) PCT Filed: Jul. 1, 2011
(86) PCT No.: PCT/EP11/61137

§ 371 Date: Apr. 3, 2013

(30) Foreign Application Priority Data
Jul. 22, 2010 (DE) 10 2010 031 945.7

(51) Int. Cl. H01L 33/60; H01L 31/18; H01L 31/0232

(52) U.S. Cl. CPC H01L 33/60; H01L 31/0232; H01L 31/18
USPC 257/98; 257/342; 438/29; 438/72

(57) ABSTRACT

A semiconductor component includes at least one optoelectronic semiconductor chip and a connecting carrier having a connecting surface on which the semiconductor chip is disposed. A reflective coating and a limiting structure are formed on the connecting carrier. The limiting structure at least partially encloses the semiconductor chip in the lateral direction, and the reflective coating at least partially extends in the lateral direction between a side surface of the semiconductor chip and the limiting structure.

This patent application is a national phase filing under section 371 of PCT/EP2011/061137, filed Jul. 1, 2011, which claims the priority of German patent application 10 2010 031 945.7, filed Jul. 22, 2010, each of which is incorporated herein by reference in its entirety.

### TECHNICAL FIELD

The present application relates to a semiconductor component, and to a method for producing a semiconductor component.

### BACKGROUND

In the case of radiation-emitting semiconductor components, for example components comprising a luminescence diode chip for generating radiation, portions of radiation that are backscattered, for instance at a luminaire housing, can be absorbed in the component, as a result of which overall the efficiency of the generation of radiation decreases.

Particularly in the case of components wherein the semiconductor chips are mounted directly onto a planar carrier, absorption by the carrier can make a significant contribution to these losses.

### SUMMARY OF THE INVENTION

In one aspect, a semiconductor component absorption losses are reduced is disclosed. Furthermore, a method for producing such a semiconductor component by means of which efficient semiconductor components can be produced cost-effectively and reliably is disclosed.

In accordance with one embodiment, a semiconductor component comprises at least one optoelectronic semiconductor chip and a connection carrier having a connection area, on which the semiconductor chip is arranged. A reflector layer is formed on the connection carrier. Furthermore, a delimiting structure is formed on the connection carrier and extends around the semiconductor chip in a lateral direction at least in regions. The reflector layer runs in a lateral direction at least in regions between a side face of the semiconductor chip and the delimiting structure.

In this context, a lateral direction is understood to mean a direction which runs along a main extension plane of the connection carrier.

By means of the delimiting structure, the lateral extent of the reflector layer is delimited at least in regions. During production, the delimiting structure is provided for preventing the material for the reflector layer from running in a lateral direction, or at least making this more difficult for said material. By means of the delimiting structure, therefore, the reflector layer can be applied to the connection carrier in a region that is precisely defined beforehand.

In a plan view of the semiconductor component, the delimiting structure extends around the semiconductor chip preferably completely. The delimiting structure can therefore comprise a self-contained structure. By way of example, the delimiting structure can be embodied in a frame-like fashion in a plan view of the semiconductor component.

On the side facing away from the connection carrier, the semiconductor chip preferably has a radiation passage area. The radiation passage area is expediently free of the reflector layer at least in regions. In particular, the radiation passage area can be embodied in a manner completely free of material for the reflector layer.

The semiconductor chip is preferably arranged directly, that is to say in an unpackaged fashion, on the connection carrier and furthermore preferably fixed to the connection carrier.

The semiconductor component can thus be embodied particularly compactly in a vertical direction, that is to say, perpendicularly to the main extension plane of the connection carrier.

The connection carrier is preferably embodied in a planar fashion. The semiconductor chip is furthermore preferably mounted in a planar fashion and preferably directly on the connection carrier. That is to say that the connection carrier is free of a cavity which is shaped in a reflector-like fashion and in which the semiconductor chip is arranged.

In one preferred configuration, the reflector layer covers the side face of the semiconductor chip at least in regions. By means of the reflector layer, it is thus possible to prevent radiation, for example portions of radiation which are generated in the semiconductor chip and emitted in a lateral direction or portions of radiation which have entered into the semiconductor chip again after back-reflection, from emerging from the semiconductor chip in a lateral direction. The radiation power emerging overall through the radiation passage area is thus increased.

In a further preferred configuration, the reflector layer directly adjoins the semiconductor chip at least in regions. In particular, the reflector layer can be integrally formed on the side face of the semiconductor chip during production. A side face of the reflector layer therefore follows the side face of the optoelectronic semiconductor chip with regard to its form.

In a further preferred configuration, the reflector layer is embodied in an electrically insulating fashion. The risk of an electrical short circuit is thus reduced.

The reflector layer is furthermore preferably embodied in a diffusely reflective fashion. The reflector layer can, for example, contain a polymer material and be embodied in a manner reflective to the radiation to be generated or to be received in the optoelectronic semiconductor chip. By way of example, the reflector layer can be provided with particles for increasing the reflectivity.

In a further preferred configuration, the reflector layer is arranged completely within the delimiting structure in a plan view of the semiconductor component. The delimiting structure thus determines the lateral extent of the reflector layers. Therefore, the delimiting structure prevents the material for the reflector layer from running laterally during production, or at least makes this more difficult for said material.

In a further preferred configuration, the semiconductor chip projects beyond the delimiting structure in a vertical direction. The semiconductor component can thus be distinguished by a particularly small thickness.

In a further preferred configuration, the connection area is formed by means of a connection area layer. The connection area layer is expediently embodied in an electrically conductive fashion.

By way of example, a layer containing a metal or metallic alloy is suitable for the connection area layer.

In one configuration variant, the delimiting structure is formed by means of a partial region of the connection area layer that is spaced apart from the connection area. The connection area and at least one part of the delimiting structure can thus emerge from a common layer during production.

In a further configuration variant, the delimiting structure is formed by means of an elevation on the connection carrier. The elevation can be applied directly on the connection carrier. In a departure from this, the delimiting structure, in particular the elevation, can be prefabricated and fixed to the connection carrier by means of a connecting layer.

In a further configuration variant, the delimiting structure is formed by means of a depression in the connection carrier. During the production of the semiconductor component, the depression and the reflector layer are preferably coordinated with one another in such a way that the surface tension of the material for the reflector layer counteracts, and preferably at least largely prevents, penetration of the material into the depression.

In a further configuration, the delimiting structure is formed by means of a region of the connection carrier that has a lower wettability for the material of the reflector layer than a material adjoining the reflector layer on that side of the connection carrier which faces the reflector layer. The region having lower wettability of the connection carrier can be formed by the surface of the connection carrier itself or by a layer applied to the connection carrier.

The region of the connection carrier having reduced wettability can directly adjoin the connection area. Furthermore, the connection area and the region having low wettability can have the same thickness, such that the connection area and the region jointly form a planar area. In other words, the delimiting structure and the region having lower wettability can terminate flush with one another in a vertical direction.

The delimiting structure can also extend around more than one optoelectronic semiconductor chip. Furthermore, within a delimiting structure, in addition to the optoelectronic semiconductor chip, it is also possible to arrange a further electronic component, which is not provided for generating or for receiving radiation. By way of example, the further component can be provided as a semiconductor chip for protection against electrostatic discharge (ESD).

Such a semiconductor chip can be completely covered by the reflector layer, such that the risk of absorption of light in the further semiconductor chip is reduced to the greatest possible extent.

In a method for producing a semiconductor component, in accordance with one embodiment, a connection carrier having a connection area is provided. A delimiting structure is arranged on the connection carrier. A semiconductor chip is arranged on the connection area. A reflector layer is formed, which runs at least in regions between the semiconductor chip and the delimiting structure.

The production method need not necessarily be carried out in the order of the above enumeration. By way of example, the connection area and the delimiting structure can be formed from a common connection area layer in a common production step.

Furthermore, it is also conceivable to arrange the delimiting structure on the connection carrier only after the semiconductor chip has already been arranged on the connection area.

The delimiting structure can be formed on the connection carrier, for example by means of a dispenser, by means of stamping, by means of printing, for instance by means of screen printing, by means of a molding method or by means of lithograph patterning.

Alternatively or supplementarily, the delimiting structure can be formed by local reduction of the wettability. This can be effected for example by means of a plasma treatment or by means of a coating. Such a coating preferably contains a material having particularly low wettability, for example a fluorinated polymer material, for instance polytetrafluoroethylene (PTFE).

As an alternative to a delimiting structure that remains in the semiconductor component, the delimiting structure can also be removed after the reflector layer has been formed. By way of example, the delimiting structure can be emplaced temporarily as a, more particularly reusable, prefabricated structure for the formation of the reflector layer. As an alternative to a prefabricated configuration, the delimiting structure can be formed on the connection carrier and subsequently removed.

In one preferred configuration, the reflector layer is applied by means of a dispenser. Such a method is suitable in particular for the cost-effective and precisely metered application of polymer material.

The method described is particularly suitable for producing a semiconductor component described further above. Features described in connection with the method can therefore also be used for the semiconductor component and vice versa.

### BRIEF DESCRIPTION OF THE DRAWINGS

Further features, configurations and expediencies will become apparent from the following description of the exemplary embodiments in conjunction with the figures.

FIGS. 1 to 7 in each case show an exemplary embodiment of a semiconductor component in schematic sectional view; and

FIGS. 8A to 8C show an exemplary embodiment of a method on the basis of intermediate steps illustrated in each case in schematic sectional view.

Elements that are identical, of identical type or act identically are provided with identical reference signs in the Figures.

The Figures and the size relationships of the elements illustrated in the figures among one another should not be regarded as to scale. Rather, individual elements and in particular layer thicknesses may be illustrated with an exaggerated size in order to enable better illustration and/or in order to afford a better understanding.

### DETAILED DESCRIPTION OF ILLUSTRATIVE EMBODIMENTS

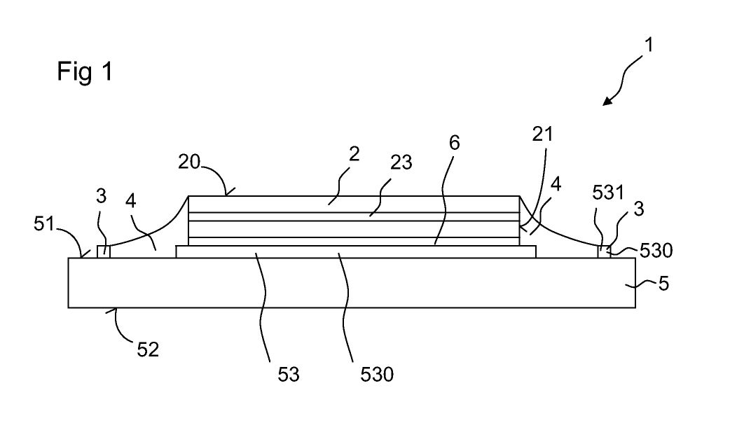

A first exemplary embodiment of a semiconductor component is illustrated schematically in sectional view in FIG. 1. The semiconductor component 1 comprises a semiconductor chip 2, which is arranged on a connection area 53 of a connection carrier 5. The semiconductor chip is fixed to the connection area by means of a connection layer 6. The semiconductor chip is therefore fixed to a planar connection carrier in an unpackaged fashion in a planar arrangement.

The semiconductor chip 2 is embodied as a luminescence diode semiconductor chip, wherein an active region 23 of the semiconductor chip is provided for generating radiation. In a departure therefrom, however, an optoelectronic semiconductor chip provided for receiving radiation can also be employed. In a lateral direction, the semiconductor chip 2 is delimited by a side face 21.

The connection carrier 5 extends in a vertical direction between a first main face 51, which faces the semiconductor chip, and a second main face 52, which faces away from the semiconductor chip 2. A connection area layer 530 is formed on the first main face 51 and forms the connection area 53 in the region of the semiconductor chip 2. A partial region 531 of the connection area layer 530 that is spaced apart from the connection area 53 forms a delimiting structure 3. During production, therefore, the delimiting structure and the connection area can emerge from a common layer.

In particular an electrically conductive material, for example a metal or a metallic alloy, is suitable for the connection area layer 530.

A reflector layer 4 is formed on the connection carrier 5 and extends in a lateral direction from the side face 21 of the semiconductor chip 2 to the delimiting structure 3. The delimiting structure 3 therefore delimits the extent of the reflector layer 4 in a lateral direction.

The reflector layer 4 covering the side face 21 is used to prevent radiation generated in the active region 23 during the operation of the semiconductor component from emerging from the semiconductor chip 2 through the side faces 21. The radiation power that emerges overall through a radiation passage area 20 of the semiconductor chip 2, said radiation passage area being formed on a side facing away from the connection carrier 5, is thereby increased.

Furthermore, the reflector layer 4 can be used to prevent radiation that has already emerged from the semiconductor component 1 from impinging on the connection carrier 5 after backscattering and from being at least partly absorbed there. The radiation power that can be utilized overall is thus increased more extensively.

The reflector layer 4 therefore prevents radiation from impinging on the connection carrier 5. Consequently, said connection carrier can be chosen or embodied independently of its optical properties. By way of example, a circuit board, for instance a printed circuit board (PCB), is suitable for the connection carrier. The circuit board can be embodied in a rigid or flexible fashion. In order to increase the thermal conductivity, the circuit board can be provided with a metal core.

By means of the reflector layer 4, the risk of radiation absorption of backscattered radiation at the connection carrier 5 is minimized even for a semiconductor chip 2 which is arranged directly onto the connection carrier 5, that is to say in an unpackaged fashion and without a cavity surrounding the semiconductor chip 2.

By means of the delimiting structure 3, the lateral extent of the reflector layer 4 can be defined in an exactly defined manner before the material for the reflector layer is applied during production.

The radiation passage area 20 is expediently free of the reflector layer 4. Radiation impinging on the radiation passage area 20 is therefore not prevented from emerging from the semiconductor chip 2 by the reflector layer 4. In a departure from the illustration shown, however, the reflector layer 4, in the region near the side face 21, can be provided with material for the reflector layer regionally in a manner governed by production. In a plan view of the semiconductor component 1, the delimiting structure is preferably arranged in a frame-like manner around the semiconductor chip 2. Preferably, the delimiting structure extends around the semiconductor chip fully circumferentially. This ensures in a simple manner that the reflector layer 4 is delimited in every direction in the lateral plane.

The reflector layer 4 is preferably embodied in a diffusely reflective fashion. By way of example, it can contain a polymer material for instance a silicone or an epoxide or a mixture composed of a silicone or an epoxide. In order to increase the reflectivity, the polymer material can be provided with titanium dioxide particles. Alternatively or supplementarily, aluminum oxide or zirconium oxide particles can also be employed. Depending on the concentration of the particles, the reflectivity of the reflector layer can be 85% or more, preferably 90% or more, for example 95%.

The reflector layer 4 is furthermore embodied in an electrically insulating fashion. In comparison with a metallic reflector layer, this reduces the risk of the semiconductor chip 2 being short-circuited by the reflector layer 4 in the region of the side face 21.

In a plan view of the semiconductor component 1, the reflector layer covers the connection area 53 in regions. In particular, the reflector layer 4 directly adjoins the connection area in that part of the latter which projects laterally beyond the semiconductor chip 2. Radiation absorption by the connection area is thus avoided in a simple manner.

The semiconductor chip 2 projects beyond the delimiting structure 3 in a vertical direction. Consequently, the thickness of the semiconductor component 1 is substantially determined by means of the thickness of the connection carrier 5 and the thickness of the semiconductor chip 2, such that the semiconductor component 1 can be produced particularly compactly.

The semiconductor chip 2, in particular the active region 23, preferably contains a III-V compound semiconductor material.

III-V compound semiconductor materials are particularly suitable for generating radiation in the ultraviolet (AlₓIn_{y}Ga_{1-x-y}N) through the visible (AlₓIn_{y}Ga_{1-x-y}N, in particular for blue to green radiation, or AlₓIn_{y}Ga_{1-x-y}P, in particular for yellow to red radiation) to the infrared (AlₓIn_{y}Ga_{1-x-y}As) spectral range. In each case 0≦x≦1, 0≦y≦1 and x+y≦1 hold true here, in particular where x≠1, y≠1, x≠0 and/or y≠0. With III-V semiconductor materials, in particular from the material systems mentioned, high internal quantum efficiencies can furthermore be obtained when generating radiation.

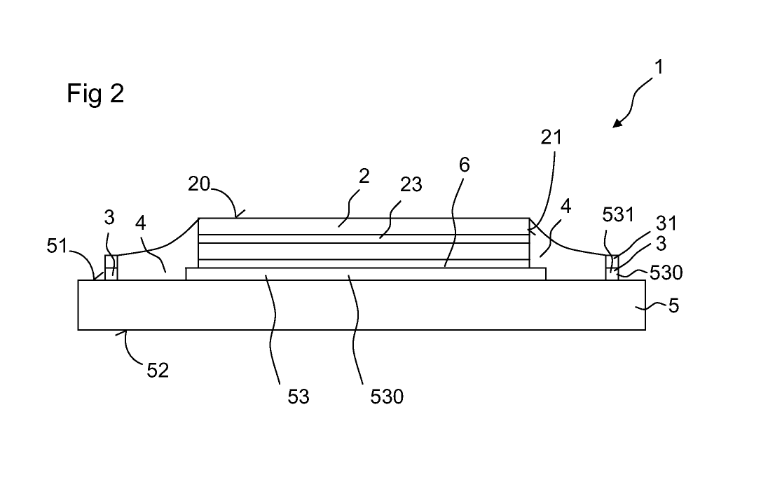

The second exemplary embodiment of a semiconductor component 1, illustrated schematically in sectional view in FIG. 2, substantially corresponds to the first exemplary embodiment described in connection with FIG. 1. In contrast thereto, the delimiting structure 3 is embodied in a multilayered fashion. On the side facing the connection carrier 5, the delimiting structure 3 is formed by means of the connection area layer 530 as in the first exemplary embodiment. On the connection area layer 530, the delimiting structure 3 has a delimiting layer 31. By means of the thickness of the delimiting layer 31, the thickness of the delimiting structure 3 can be set largely independently of the thickness of the connection area layer 530. For increasing the thickness of the delimiting structure 3, therefore, it is not necessary to increase the thickness of the connection area layer 530. The material requirement can thus be reduced.

The thicker the delimiting structure 3, the lower the risk of material for the reflector layer 4 running beyond the delimiting structure 3 during the production of the semiconductor component 1. The delimiting layer 31 can be embodied as an electrolytic reinforcement, for example.

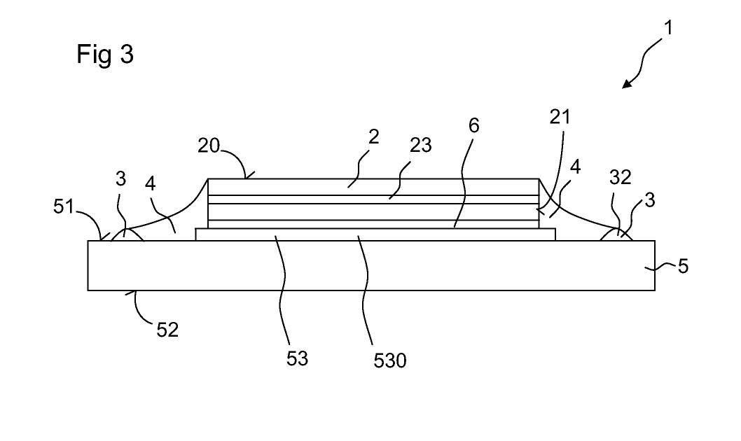

The third exemplary embodiment, illustrated schematically in sectional view in FIG. 3, substantially corresponds to the first exemplary embodiment described in connection with FIG. 1. In contrast thereto, the delimiting structure 3 is formed by means of an elevation 32. In this case, therefore, the delimiting structure 3 can be embodied totally independently of the connection area 53. In particular, material which is electrically insulating and would not be suitable for the connection area 53 can also be employed for the delimiting structure.

By way of example, a plastic, for instance a silicone, an epoxide or a resist is suitable for the elevation.

Such a delimiting structure 3 can be applied to the connection carrier 5 for example by means of a dispenser, by means of a stamp, by means of a molding method, for instance an injection molding method or a transfer molding method, or by means of printing.

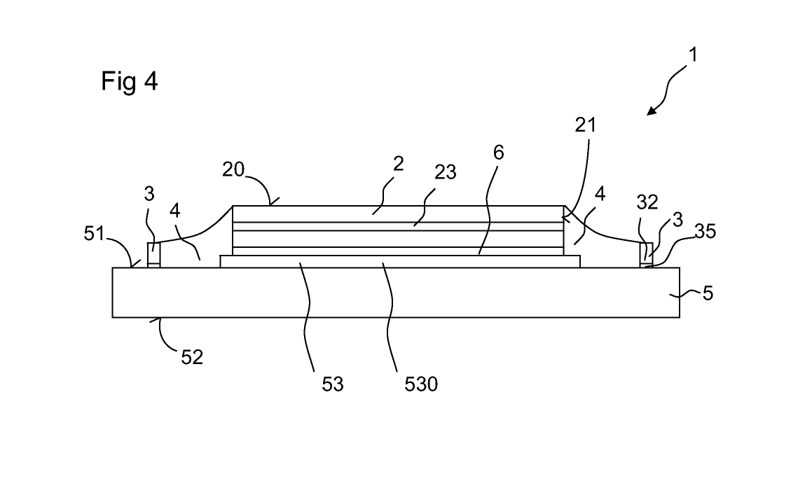

The fourth exemplary embodiment of a semiconductor component 1, illustrated in FIG. 4, substantially corresponds to the third exemplary embodiment described in connection with FIG. 3. In contrast thereto, the delimiting structure 3 is formed by means of an elevation 32 which is prefabricated and is subsequently fixed to the connection carrier 5. The fixing is effected by means of a connecting layer 35, for example an adhesive layer, which is formed between the elevation 32 and the first main face 51 of the connection carrier.

In this case, the material for the delimiting structure can be chosen in wide ranges. By way of example, a metal, for instance in the form of a stamped metal sheet, a ceramic or a plastic can be employed.

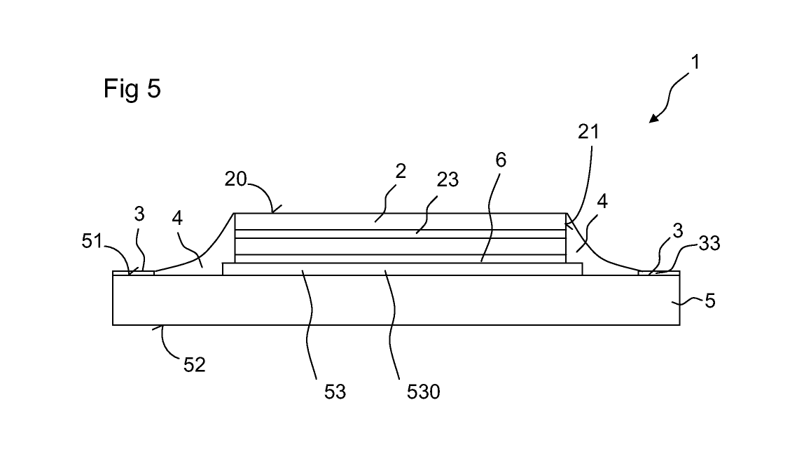

The fifth exemplary embodiment of a semiconductor component, illustrated schematically in sectional view in FIG. 5, substantially corresponds to the third exemplary embodiment described in connection with FIG. 3.

In contrast thereto, the delimiting structure 3 is formed by means of a coating formed in a region 33 on the connection carrier 5. The coating is formed in such a way that the material for the reflector layer 4, during the production thereof, does not wet the region 33 or wets it only weakly at least in comparison with an untreated exposed main face of the connection carrier.

The region 33 is therefore formed by a coating of the connection carrier. The coating can contain a primer material, for example, which reduces the wettability of the first main face of the connection carrier. By way of example, a fluorinated polymer material, for instance PTFE, is suitable as a material having low wettability.

Even small layer thicknesses, for example layer thicknesses of between 20 nm and 200 nm inclusive, can be sufficient for the coating. However, layer thicknesses of 1 μm or more can also be expedient.

During the formation of the reflector layer, the lateral extent of the reflector layer 4 is therefore controlled predominantly on the basis of the different wettability in this exemplary embodiment. Such a coating can also be employed in addition to the delimiting structures described in connection with the further exemplary embodiments. By way of example, the delimiting structure can be an elevation provided with a coating for reducing the wettability.

In a departure from the exemplary embodiment shown, the region 33 can also be formed directly on the first main face 51 of the connection carrier 5. By way of example, the first main face 51 can be locally modified by means of a plasma treatment in the region 33 such that the wettability for material for the reflector layer 4 is reduced.

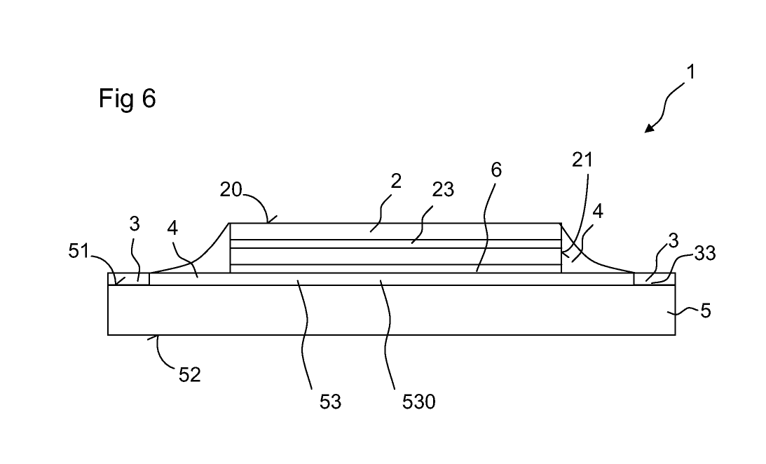

The sixth exemplary embodiment of a semiconductor component, illustrated in FIG. 6, substantially corresponds to the fifth exemplary embodiment described in connection with FIG. 5. In contrast thereto, the region 33 forming the delimiting structure 3 directly adjoins the connection area 53. The connection carrier 5 having the connection area 53 can therefore be leveled by means of the coating in the region 33.

The connection area 53 and the coating in the region 33 terminate flush with one another in a vertical direction, such that a planar surface arises. The different wettability properties, that is to say a lower wettability in the region 33, have the effect that the extent of the reflector layer 4 is delimited by the delimiting structure 3 in a lateral direction during production.

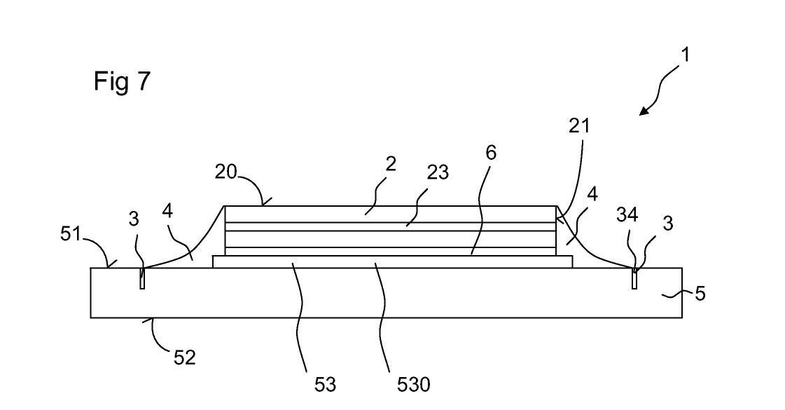

The seventh exemplary embodiment, described in connection with FIG. 7, substantially corresponds to the third exemplary embodiment described in connection with FIG. 3. In contrast thereto, the delimiting structure 3 is not formed by means of elevations, but rather by means of depressions 34. The extent of the depressions is adapted to the material for the reflector layer 4, in particular with regard to the surface tension thereof, in such a way that the material of the reflector layer 4 does not run beyond the depressions 34 in a lateral direction.

The depression 34 can be introduced for example mechanically, for instance by means of scribing or sawing, or by means of coherent radiation. Alternatively, a chemical method, for example a wet-chemical or a dry-chemical method, can also be employed.

In contrast to the third exemplary embodiment, therefore, the delimiting structure 3 can be formed without elevations projecting beyond the first main face 51 of the carrier in the direction of the radiation passage area 20. In the exemplary embodiments described, in each case only an individual semiconductor chip 2 surrounded by a delimiting structure 3 is shown, merely for the sake of a simplified illustration. In a departure therefrom, however, a plurality of semiconductor chips can also be arranged within a delimiting structure. The semiconductor chips can be optoelectronic semiconductor chips provided for generating or for receiving radiation, or an electronic component. An electronic component can be completely embedded into the reflector layer 4 in order to avoid absorption of radiation, such that a surface of the component that faces away from the connection carrier 5 can also be covered by the reflector layer.

The electronic component can be embodied for example as an ESD protective diode for the optoelectronic semiconductor chip 2.

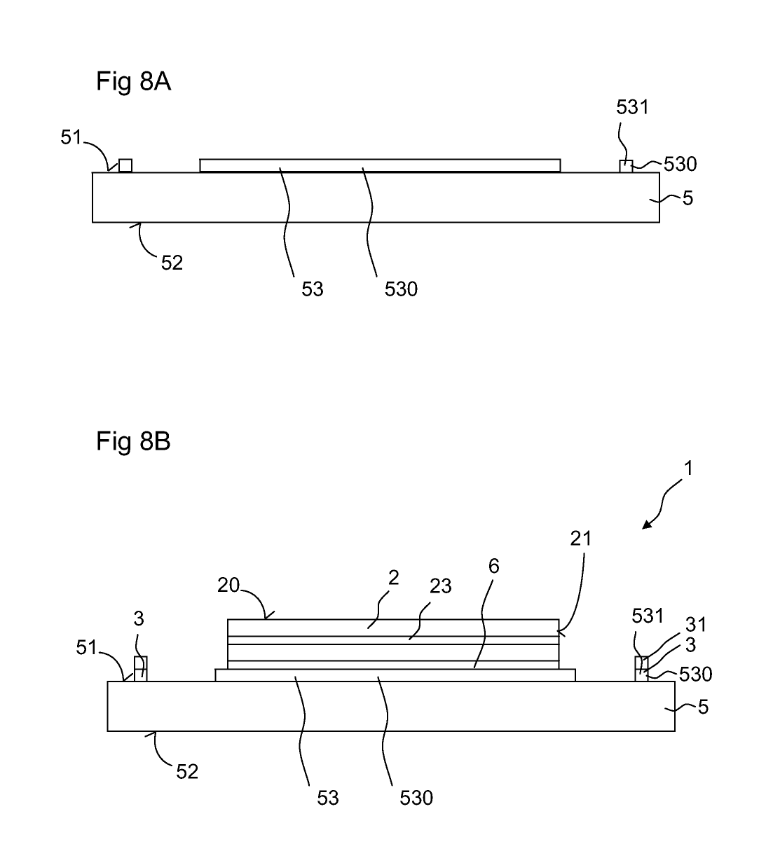

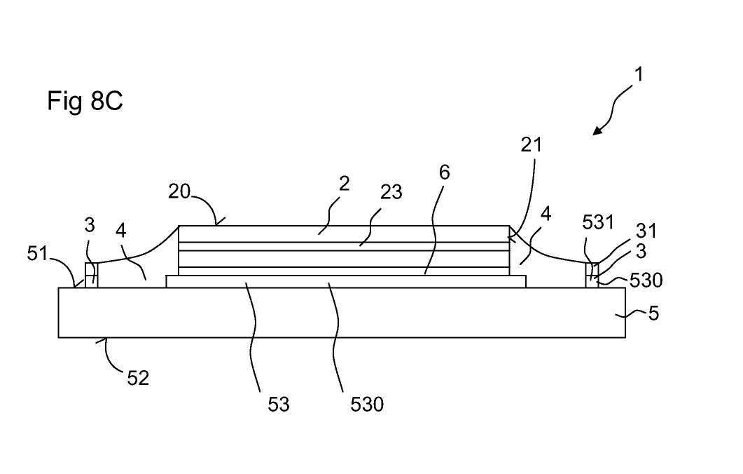

A method for producing a semiconductor component is illustrated schematically on the basis of intermediate steps in FIGS. 8A to 8C, wherein the method is shown merely by way of example for a semiconductor component embodied in accordance with the second exemplary embodiment (FIG. 2).

A connection carrier 5 is provided, wherein a connection area layer 530 is formed on the connection carrier 5. The connection area layer 530 is subdivided into two partial regions that are spaced apart from one another, wherein one partial region forms the connection area 53 and a further partial region 531, extending around the connection area 53, is provided for the formation of a delimiting structure (FIG. 8A).

A delimiting layer 31 is applied to the partial region 531, as illustrated in FIG. 8B. This can be effected for example by means of electrolytic reinforcement of the partial region 531. Alternatively or supplementarily, the delimiting layer can be applied by vapor deposition or sputtering.

A semiconductor chip 2 having an active region 23 provided for generating radiation is fixed to the connection area 53 by means of a connection layer 6, for example a solder or an electrically conductive adhesive. After the optoelectronic semiconductor chip 2 has been fixed, it is possible, as illustrated in FIG. 8C, to apply a reflector layer 4 in such a way that the latter extends in a lateral direction from a side face 21 of the semiconductor chip 2 toward the delimiting structure 3. The delimiting structure 3 can be used to prevent, in a simple and reliable manner, the reflector layer 4 from running in a lateral direction during production. In the case of a predefined quantity of material for the reflector layer, therefore, both the extent of the reflector layer in a lateral direction and the thickness of the reflector layer are predefined by means of the delimiting structure 3.

The reflector layer 4 can thus be applied in a particularly simple and reproducible manner. By way of example, the reflector layer can be applied by means of a dispenser.

In a departure from the exemplary embodiment described, the delimiting structure 3 can also be removed after the formation of the reflector layer 4. By way of example, the delimiting structure 3 can be embodied as a prefabricated structure that is placed temporarily onto the connection carrier 5. Such a delimiting structure can be embodied for example as a structure for a screen printing method and can be reused during production for a multiplicity of semiconductor components. Alternatively, a temporary delimiting structure 3 can be destroyed during removal, for example chemically, for instance by means of etching or by means of a solvent.

The invention is not restricted by the description on the basis of the exemplary embodiments. Rather, the invention encompasses any novel feature and also any combination of features, which in particular includes any combination of features in the patent claims, even if this feature or this combination itself is not explicitly specified in the patent claims or the exemplary embodiments.

1-15. (canceled)

16. A semiconductor component comprising:
an optoelectronic semiconductor chip;
a connection carrier having a connection area, the semiconductor chip being arranged on the connection area of the connection carrier;
a reflector layer disposed on the connection carrier; and
a delimiting structure disposed on the connection carrier and extending around the semiconductor chip in a lateral direction at least in regions, wherein the reflector layer runs in a lateral direction at least in regions between a side face of the semiconductor chip and the delimiting structure.

17. The semiconductor component according to claim 16, wherein the reflector layer directly adjoins the semiconductor chip at least in regions.

18. The semiconductor component according to claim 16, wherein the reflector layer comprises an electrically insulating material.

19. The semiconductor component according to claim 16, wherein the reflector layer is arranged completely within the delimiting structure in a plan view of the semiconductor component.

20. The semiconductor component according to claim 16, wherein the semiconductor chip projects beyond the delimiting structure in a vertical direction.

21. The semiconductor component according to claim 16, wherein the connection area is formed by a connection area layer and wherein the delimiting structure is formed by a partial region of the connection area layer that is spaced apart from the connection area.

22. The semiconductor component according to claim 16, wherein the delimiting structure is formed by an elevation on the connection carrier.

23. The semiconductor component according to claim 22, wherein the elevation is fixed to the connection carrier by a connecting layer.

24. The semiconductor component according to claim 16, wherein the delimiting structure is formed by a depression in the connection carrier.

25. The semiconductor component according to claim 16, wherein the delimiting structure is formed by a region on the connection carrier that has a lower wettability for a material of the reflector layer than a material adjoining the reflector layer on the side facing the connection carrier.

26. The semiconductor component according to claim 16, wherein the semiconductor component includes only one optoelectronic semiconductor chip.

27. The semiconductor component according to claim 16, wherein the semiconductor component includes a plurality of semiconductor chips.

28. A method for producing a semiconductor component, the method comprising:
providing a connection carrier having a connection area;
arranging a delimiting structure on the connection carrier;
arranging a semiconductor chip on the connection area; and
forming a reflector layer that runs at least in regions between the semiconductor chip and the delimiting structure.

29. The method according to claim 28, wherein forming the reflector layer comprises applying the reflector layer using a dispenser.

30. The method according to claim 28, wherein the delimiting structure is formed by local reduction of wettability.

31. The method according to claim 28, further comprising removing the delimiting structure after the reflector layer has been formed.

32. The method according to claim 28, wherein the semiconductor chip comprises an optoelectronic semiconductor chip.

33. A semiconductor component comprising:
a semiconductor chip;
a connection carrier having a connection area, wherein the semiconductor chip is arranged on the connection area of the connection carrier;
a reflector layer disposed on the connection carrier; and
a delimiting structure disposed on the connection carrier and extending around the semiconductor chip in a lateral direction at least in regions;
wherein the reflector layer runs in a lateral direction at least in regions between a side face of the semiconductor chip and the delimiting structure; and
wherein the semiconductor chip projects beyond the delimiting structure in a vertical direction.
